(19) United States
(12) Patent Application Publication
(10) Pub. No.: US 2026/0231337 A1
(43) Pub. Date: Aug. 6, 2026

(54) INTEGRATED PASSIVE COMPONENT

(71) Applicant: Murata Manufacturing Co., Ltd., Kyoto-fu (JP)

(72) Inventor: Jyou KIKURA, Nagaokakyo-shi (JP)

(73) Assignee: Murata Manufacturing Co., Ltd., Kyoto-fu (JP)

(21) Appl. No.: 19/636,288

(22) Filed: Apr. 1, 2026

Related U.S. Application Data
(63) Continuation of application No. PCT/JP2024/025933, filed on Jul. 19, 2024.

(30) Foreign Application Priority Data
Oct. 24, 2023 (JP) 2023-182460

(51) Int. Cl. H05K 1/182; H05K 1/02

(52) U.S. Cl. CPC H05K 1/182; H05K 1/0298; H05K 2201/10015

(57) ABSTRACT

A capacitor is disposed on an upper surface, which is one surface of a support substrate. A first insulating film covering the capacitor is disposed on the support substrate. A second insulating film is disposed on the first insulating film. A multilayer wiring layer including multiple wiring layers and multiple third insulating films, stacked in an alternating manner, is disposed on the second insulating film. The multilayer wiring layer includes an inductor constituted by conductor patterns in wiring layers. The weight-average molecular weight of the resin forming the second insulating film is greater than the weight-average molecular weight of the resin forming the third insulating film.

### CROSS-REFERENCE TO RELATED APPLICATIONS

This application claims benefit of priority to International Patent Application No. PCT/JP2024/025933, filed Jul. 19, 2024, and to Japanese Patent Application No. 2023-182460, filed Oct. 24, 2023, the entire contents of each are incorporated herein by reference.

### BACKGROUND

### Technical Field

The present disclosure relates to integrated passive components.

### Background Art

Integrated passive components, in which passive elements are integrated, are used to achieve higher degrees of integration in communication modules as described, for example, in Japanese Unexamined Patent Application Publication No. 2021-174803. An integrated passive component includes a support substrate and a capacitor, an inductor, and other components mounted on the support substrate. The capacitor is covered by an insulating film composed of an inorganic insulating material. The inductor is formed of conductor patterns in a multilayer wiring layer that is disposed on the insulating film covering the capacitor. The support substrate is composed of a ceramic material such as silicon nitride, and the insulating layers of the multilayer wiring layer are composed of an insulating resin.

### SUMMARY

Thermal stress caused by differences between the coefficients of linear expansion of the support substrate and inorganic insulating film and the coefficient of linear expansion of the insulating layers constituting the multilayer wiring layer can result in cracks at the interface between the inorganic insulating layer and the multilayer wiring layer. Peeling can also occur at the interface between the inorganic insulating layer and the multilayer wiring layer. In particular, making the conductor patterns and insulating layers constituting the multilayer wiring layer thicker in order to improve electrical characteristics can result in cracks and peeling being more likely to occur. Therefore, the present disclosure provides an integrated passive component that is less susceptible to cracks and peeling.

According to an aspect of the present disclosure, an integrated passive component includes a support substrate, a capacitor, a first insulating film, a second insulating film, and a multilayer wiring layer. The capacitor is disposed on an upper surface, which is one surface of the support substrate. The first insulating film is disposed on the support substrate and covers the capacitor. The second insulating film is disposed on the first insulating film. The multilayer wiring layer includes multiple wiring layers and multiple third insulating films stacked in an alternating manner on the second insulating film. The multilayer wiring layer includes an inductor constituted by conductor patterns inside wiring layers. A weight-average molecular weight of resin forming the second insulating film is greater than a weight-average molecular weight of resin forming the third insulating films.

According to another aspect of the present disclosure, an integrated passive component includes a support substrate, a capacitor, a first insulating film, a second insulating film, and a multilayer wiring layer. The capacitor is disposed on an upper surface, which is one surface of the support substrate. The first insulating film is disposed on the support substrate and covers the capacitor. The second insulating film is disposed on the first insulating film. The multilayer wiring layer includes a plurality of wiring layers and a plurality of third insulating films stacked in an alternating manner on the second insulating film. The multilayer wiring layer includes an inductor configured by a conductor pattern inside the wiring layer. Breaking elongation of resin forming the second insulating film is greater than breaking elongation of resin forming the third insulating films.

The second insulating film, which has a relatively large weight-average molecular weight, has higher toughness than the third insulating films, which have a relatively small weight-average molecular weight. This makes it less likely for cracks and peeling to occur at the interface between the first insulating film and the second insulating film. Furthermore, by adopting a configuration in which the breaking elongation of the resin forming the second insulating film is greater than the breaking elongation of the resin forming the third insulating films, cracks and peeling are less likely to occur at the interface between the first insulating film and the second insulating film.

### BRIEF DESCRIPTION OF THE DRAWINGS

FIG. 1 is a cross-sectional view of an integrated passive component according to a First Embodiment;

FIG. 2A is a diagram illustrating the positional relationship of components of an integrated passive component according to a Second Embodiment in plan view, and FIG. 2B is an equivalent circuit diagram of the integrated passive component according to the Second Embodiment;

FIG. 3A is a diagram illustrating the positional relationship in plan view between the conductor patterns of a lower electrode layer and the conductor patterns of an upper electrode layer, FIG. 3B is a diagram illustrating the positional relationship in plan view between the conductor patterns of the upper electrode layer and the conductor patterns of a first wiring layer, and FIG. 3C is a diagram illustrating the positional relationship in plan view between the conductor patterns of the first wiring layer and the conductor patterns of a second wiring layer;

FIG. 4A is a diagram illustrating the positional relationship in plan view between the conductor patterns of the second wiring layer and the conductor patterns of a third wiring layer, and FIG. 4B is a diagram illustrating the positional relationship in plan view between the conductor patterns of the third wiring layer and multiple external connection terminals;

FIG. 5 is a cross-sectional view taken along single-dot dash line 5-5 in FIG. 2A;

FIGS. 6A, 6B, and 6C are cross-sectional views of the integrated passive component according to the Second Embodiment at intermediate stages during its manufacture;

FIGS. 7A and 7B are cross-sectional views of the integrated passive component according to the Second Embodiment at intermediate stages during its manufacture;

FIG. 8A is an equivalent circuit diagram of an integrated passive component according to a Third Embodiment, and FIG. 8B is a diagram illustrating the positional relationship in plan view of conductor patterns constituting the integrated passive component according to the Third Embodiment; and

FIG. 9A is a graph illustrating the simulation results of insertion loss (S₂₁) of the integrated passive component according to the Third Embodiment, and FIG. 9B is a graph illustrating the relationship between the peak value of the insertion loss S₂₁ and the thickness of a second insulating film.

### DETAILED DESCRIPTION

### First Embodiment

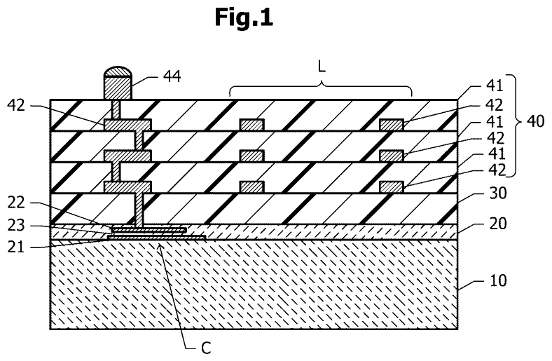

Referring to FIG. 1, an integrated passive component according to a First Embodiment will be described.

FIG. 1 is a cross-sectional view of the integrated passive component according to the First Embodiment. The integrated passive component according to the First Embodiment includes a support substrate 10, a capacitor C, a first insulating film 20, a second insulating film 30, and a multilayer wiring layer 40 disposed on one surface (hereinafter referred to as the upper surface) of the support substrate 10. The capacitor C includes a lower electrode 21, an upper electrode 22, and a dielectric film 23 disposed between the lower electrode 21 and the upper electrode 22.

The first insulating film 20 is disposed on the support substrate 10 and covers the capacitor C. The second insulating film 30 is disposed on the first insulating film 20, and the multilayer wiring layer 40 is disposed on the second insulating film 30. The multilayer wiring layer 40 includes multiple wiring layers and multiple third insulating films 41 stacked in an alternating manner. Each of the multiple wiring layers includes multiple conductor patterns 42. Some of the multiple conductor patterns 42 form an inductor L. A terminal 44 for external connection is disposed on the multilayer wiring layer 40. The terminal 44 is connected to the upper electrode 22 of the capacitor C via the multiple conductor patterns 42 in the multilayer wiring layer 40.

The “third insulating film 41” is present, for example, between the conductor patterns 42 of two vertically adjacent wiring layers, and in areas where no conductor patterns 42 are disposed, two vertically adjacent third insulating films 41 are in contact with each other. In areas where two third insulating films 41 are in contact with each other, the interface therebetween might not be clearly visible. The “third insulating films 41” also include an insulating layer that covers the surfaces of the conductor patterns 42 of the uppermost wiring layer and the surface of the third insulating film 41 that forms the underlying layer, and an insulating layer between the conductor patterns 42 of the lowermost wiring layer and the first insulating film 20.

Next, the materials of each component will be described. The support substrate 10, the dielectric film 23 of the capacitor C, and the first insulating film 20 are formed of inorganic insulating materials primarily containing silicon and nitrogen as constituent elements. For example, silicon nitride (SiN) ceramic is used for the support substrate 10, and amorphous silicon nitride is used for the dielectric film 23 of the capacitor C and the first insulating film 20. Here, “an inorganic insulating material primarily contains a specific element as a constituent element” means that the inorganic insulating material may contain elements other than the specific element to the extent that they do not significantly affect the coefficient of linear expansion and volume resistivity of the material.

For example, if the molar concentration of an element contained as a constituent element in an inorganic insulating material is 50 mol % or more, it can be said that “the inorganic insulating material primarily contains that element as a constituent element”. An “element contained as a constituent element” may also consist of multiple elements, such as SiN. In this case, if the sum of the molar concentrations of the multiple elements is 50 mol % or more, it can be said that “the inorganic insulating material primarily contains the multiple elements as constituent elements.” For example, if the inorganic insulating material is SiN and the sum of the molar concentrations of Si and N is 50 mol % or more, the inorganic insulating material can be said to primarily contain Si and N as constituent elements. For example, in silicon oxynitride (SiON), which is silicon nitride containing oxygen, if the sum of the molar concentrations of Si, O, and N is 50 mol % or more, the inorganic insulating material can be said to primarily contain Si, O, and N. Similarly, in silicon carbonitride (SiCN), which is silicon nitride containing carbon, when the sum of the molar concentrations of Si, C, and N is 50 mol % or more, this inorganic insulating material can be said to primarily contain Si, C, and N. Any inorganic insulating material can be said to primarily contain at least Si and N.

A SiN ceramic substrate having an amorphous SiN film disposed thereon may be used as the support substrate 10. In this case, the lower electrode 21 of the capacitor C is disposed on the amorphous SiN film.

The second insulating film 30 and the third insulating films 41 are composed of an insulating resin, such as an epoxy-based, polyimide-based, or benzocyclobutene-based resin. The second insulating film 30 and the third insulating films 41 may be composed of a resin containing a photosensitive material. The lower electrode 21 and the upper electrode 22 of the capacitor C and the conductor patterns 42 are composed of a metal material, and are preferably composed of a metal material having high conductivity such as Au, Al, or Cu or a metal material containing Cu as a main component. The conductor patterns 42 are preferably composed of Cu or a metal material containing Cu as a main component, which can be easily formed into a thick film.

The weight-average molecular weight of the resin used for the second insulating film 30 is larger than the weight-average molecular weight of the resin used for the multiple third insulating films 41 in the multilayer wiring layer 40. The second insulating film 30 and the third insulating films 41 can be formed using, for example, a vacuum lamination method, a spin coating method, or the like. The second insulating film 30 and the third insulating films 41 having different weight-average molecular weights can be formed by appropriately selecting a semi-cured film used in a vacuum lamination method or a coating agent used in a spin coating method.

Next, the excellent effects of the First Embodiment will be described.

Resins with relatively high weight-average molecular weights have the characteristic of higher toughness (breaking elongation) than resins with relatively low weight-average molecular weights. Specifically, the toughness of the second insulating film 30 is higher than that of the third insulating films 41. Therefore, when stress is applied between the support substrate 10 and the multilayer wiring layer 40, the second insulating film 30 can expand and contract significantly without its molecular chains breaking. The stress-induced energy required for breakdown (peeling) of resin is consumed by the expansion and contraction deformation of the second insulating film 30. As a result, cracks and peeling due to the difference in coefficient of linear expansion between the support substrate 10 and the third insulating films 41 can be suppressed. This improves the reliability of the integrated passive component.

Generally, the coefficient of linear expansion of resin is higher than that of inorganic materials such as SiN ceramic. By incorporating inorganic filler into the second insulating film 30 and the third insulating films 41 and bringing the coefficients of linear expansion of the second insulating film 30 and the third insulating films 41 closer to that of the support substrate 10, it is possible to suppress the occurrence of cracks and peeling caused by thermal stress. However, when a filler-containing resin is used for the second insulating film 30 and the third insulating films 41, it becomes difficult to perform microfabrication. As a result, it becomes more difficult to reduce the size of the integrated passive component.

In the First Embodiment, it is possible to reduce the size of the integrated passive component because there is no need to use a filler-containing resin for the second insulating film 30 and the third insulating films 41. Note that a filler may be incorporated to the extent that it does not impair microfabrication.

Furthermore, to prevent cracks and peeling due to thermal stress, it is preferable to minimize the difference in coefficient of linear expansion between materials on both sides of an interface. In the First Embodiment, the coefficients of linear expansion of the support substrate 10 and the first insulating film 20, which are composed of an inorganic insulating material, are smaller than that of the third insulating film 41. To avoid an increase in the difference in coefficient of linear expansion at the interface between different materials, it is preferable to use a resin material for the second insulating film 30 that has a coefficient of linear expansion equal to or lower than that of the third insulating films 41.

Next, an example of a method for measuring the weight-average molecular weight of an insulating resin material will be described.

First, all parts of the integrated passive component other than the insulating film to be measured are removed, and the insulating film to be measured is extracted as a single film or powder. The weight-average molecular weight of the extracted film or powder can be measured using gel permeation chromatography or mass spectrometry.

Next, a modification of the First Embodiment will be described. In the First Embodiment, the magnitude relationship between the weight-average molecular weights of the second insulating film 30 and the third insulating films 41 is restricted, but the magnitude relationship between the crosslink densities may also be restricted. For example, if a resin having a lower crosslink density than that of the third insulating films 41 is used as the second insulating film 30, the toughness of the second insulating film 30 will generally be higher than that of the third insulating films 41. Therefore, similarly to the First Embodiment, an excellent effect of increasing the reliability of the integrated passive component can be obtained.

### Second Embodiment

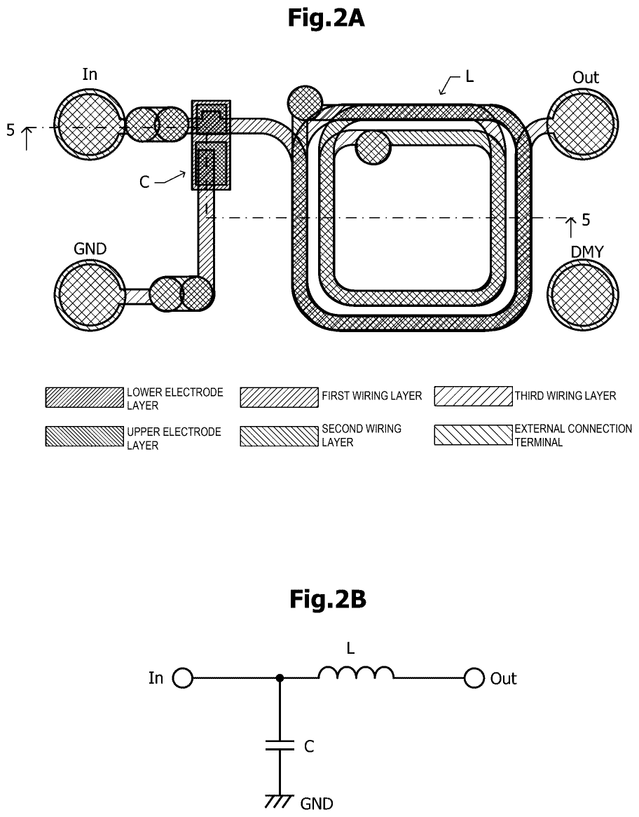

Next, an integrated passive component according to a Second Embodiment will be described with reference to FIGS. 2A to 7B. Below, description of configurations common to the integrated passive component illustrated in FIG. 1 will be omitted.

FIG. 2A is a diagram illustrating the positional relationship of the components of the integrated passive component according to the Second Embodiment in plan view, and FIG. 2B is an equivalent circuit diagram of the integrated passive component according to the Second Embodiment. The integrated passive component according to the Second Embodiment includes a capacitor C, an inductor L, an input terminal In, an output terminal Out, a ground terminal GND, and a dummy terminal DMY provided on a single insulating substrate.

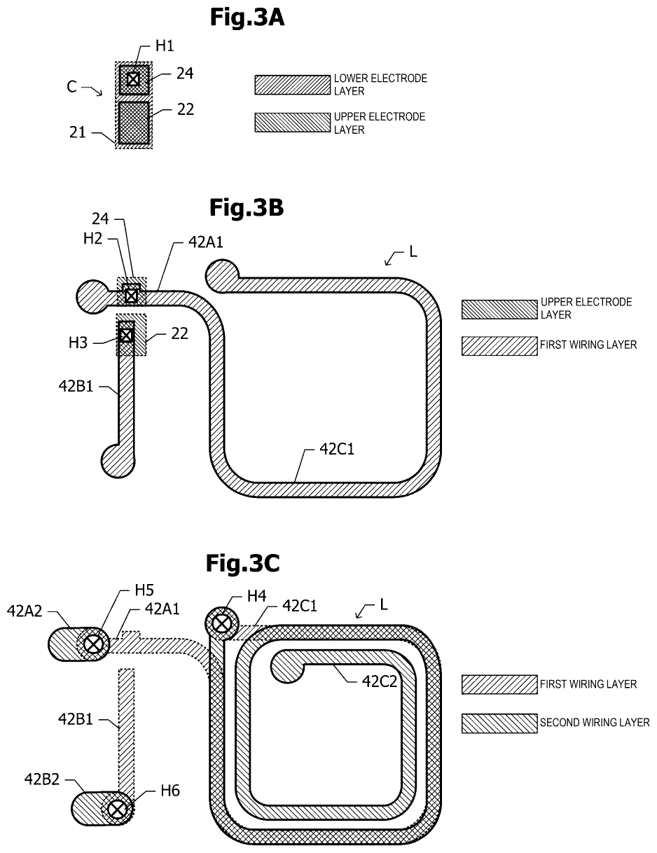

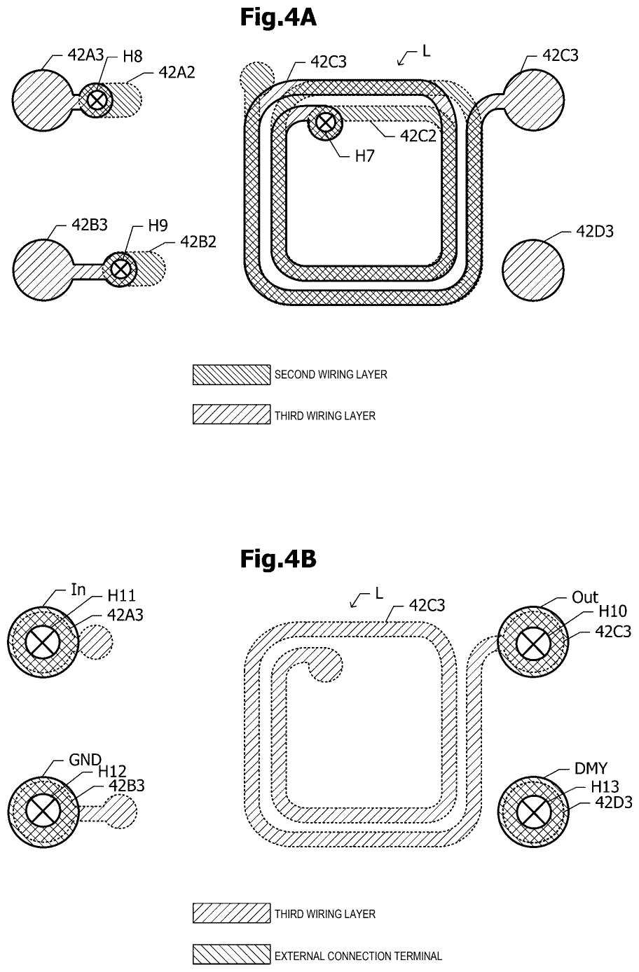

On the substrate, multiple conductor layers and multiple insulating films that insulate adjacent conductor layers from one another are stacked in an alternating manner. In the Second Embodiment, five conductor layers are stacked, and these conductor layers are referred to, in order from the substrate side, as a lower electrode layer, an upper electrode layer, a first wiring layer, a second wiring layer, and a third wiring layer. Multiple external connection terminals, such as the input terminal In, the output terminal Out, and the ground terminal GND, are disposed on the uppermost insulating film. In FIG. 2A, hatching with different shadings and orientations is applied to each conductor layer. The shape and positional relationship of the conductor patterns disposed in each conductor layer will be described in detail later with reference to FIGS. 3A to 4B.

As illustrated in FIG. 2B, the inductor L is connected between the input terminal In and the output terminal Out, and the capacitor C is connected between the input terminal In and the ground terminal GND. The integrated passive component according to the Second Embodiment functions as a low-pass filter.

The configuration of the conductor patterns of two vertically adjacent conductor layers will be described with reference to FIGS. 3A to 4B. In FIGS. 3A to 4B, the conductor pattern of a relatively lower wiring layer is indicated by dashed lines.

FIG. 3A is a diagram illustrating the positional relationship between the conductor patterns of the lower electrode layer and the conductor patterns of the upper electrode layer in plan view. A lower electrode 21 of the capacitor C is disposed in the lower electrode layer. An upper electrode 22 of the capacitor C and another conductor pattern 24 are disposed in the upper electrode layer. In plan view, the upper electrode 22 and the conductor pattern 24 overlap the lower electrode 21. The conductor pattern 24 is connected to the lower electrode 21 through a via hole H1 provided in the insulating film.

FIG. 3B illustrates the positional relationship between the conductor patterns of the upper electrode layer and the conductor patterns of the first wiring layer in plan view. Conductor patterns 42A1, 42B1, and 42C1 are disposed in the first wiring layer. The conductor pattern 42C1 extends approximately once around the outer periphery of a rounded square shaped disposed at a position that does not overlap the capacitor C in plan view. The conductor pattern 42A1 extends from one end portion of the conductor pattern 42C1 toward the conductor pattern 24 of the upper electrode layer and passes through a position where it overlaps the conductor pattern 24. The conductor pattern 42C1 forms part of the inductor L. The conductor pattern 42A1 is connected to the conductor pattern 24 of the upper electrode layer through a via hole H2. That is, the conductor patterns 42A1 and 42C1 are connected to the lower electrode 21 of the capacitor C (FIG. 3A) via the conductor pattern 24.

One end of the conductor pattern 42B1 overlaps the upper electrode 22 of the capacitor C. The conductor pattern 42B1 is connected to the upper electrode 22 through a via hole H3.

FIG. 3C illustrates the positional relationship between the conductor patterns of the first wiring layer and the conductor patterns of the second wiring layer in plan view. The second wiring layer includes a conductor pattern 42C2 that forms part of the inductor L, as well as other conductor patterns 42A2 and 42B2. The conductor pattern 42C2 includes a portion that substantially overlaps the conductor pattern 42C1 of the first wiring layer and a portion that is disposed inside the overlapping portion and extends parallel to the portion on the outside through substantially an entire turn. In other words, the conductor pattern 42C2 has a spiral shape with approximately two turns. The outer end portion of the conductor pattern 42C2 is connected to one end portion of the conductor pattern 42C1 of the first wiring layer through a via hole H4.

The conductor pattern 42A2 is connected to an end portion of the conductor pattern 42A1 of the first wiring layer through a via hole H5. The conductor pattern 42B2 is connected to an end portion of the conductor pattern 42B1 of the first wiring layer through a via hole H6.

FIG. 4A is a diagram illustrating the positional relationship between the conductor patterns of the second wiring layer and the conductor patterns of the third wiring layer in plan view. A conductor pattern 42C3 forming part of the inductor L, as well as other conductor patterns 42A3, 42B3, and 42D3 are disposed in the third wiring layer. The conductor pattern 42C3 has a spiral shape and is disposed so as to overlap the inner-periphery-side and the outer-periphery-side conductor patterns of the conductor pattern 42C2 of the second wiring layer. The inner end portion of the conductor pattern 42C3 is connected to the inner end portion of the conductor pattern 42C2 of the second wiring layer through a via hole H7. The outer end portion of the conductor pattern 42C3 is an inner-layer land having a circular planar shape.

The conductor patterns 42A3 and 42B3 are connected to the conductor patterns 42A2 and 42B2 of the second wiring layer through via holes H8 and H9, respectively. The end portions of the conductor patterns 42A3 and 42B3 are each formed as inner-layer lands with a circular planar shape. Furthermore, the conductor pattern 42D3 having an isolated circular planar shape that is not connected to other conductor patterns in layers below the third wiring layer is disposed in the third wiring layer.

FIG. 4B is a diagram illustrating the positional relationship between the conductor patterns of the third wiring layer and multiple external connection terminals in plan view. The multiple external connection terminals include the input terminal In, the output terminal Out, the ground terminal GND, and the dummy terminal DMY. The output terminal Out is connected to an inner-layer land portion of the conductor pattern 42C3 through a via hole H10. The input terminal In is connected to an inner-layer land portion of the conductor pattern 42A3 through a via hole H11. The ground terminal GND is connected to an inner-layer land portion of the conductor pattern 42B3 through a via hole H12. The dummy terminal DMY is connected to the conductor pattern 42D3 through a via hole H13.

That is, the conductor patterns 42C1, 42C2, and 42C3 form the inductor L, the coil axis of which is oriented in the thickness direction of the substrate. One end portion of the inductor L is connected to the lower electrode 21 (FIG. 3A) of the capacitor C via the conductor pattern 24 (FIGS. 3A and 3B). The other end portion of the inductor L is connected to the output terminal Out (FIG. 4B). The upper electrode 22 (FIG. 3A) of the capacitor C is connected to the ground terminal GND (FIG. 4B) via the conductor patterns 42B1, 42B2, and 42B3 (FIGS. 3B, 3C, and 4A). In plan view, the inductor L (FIG. 2A) is disposed so as not to overlap the capacitor C (FIG. 2A).

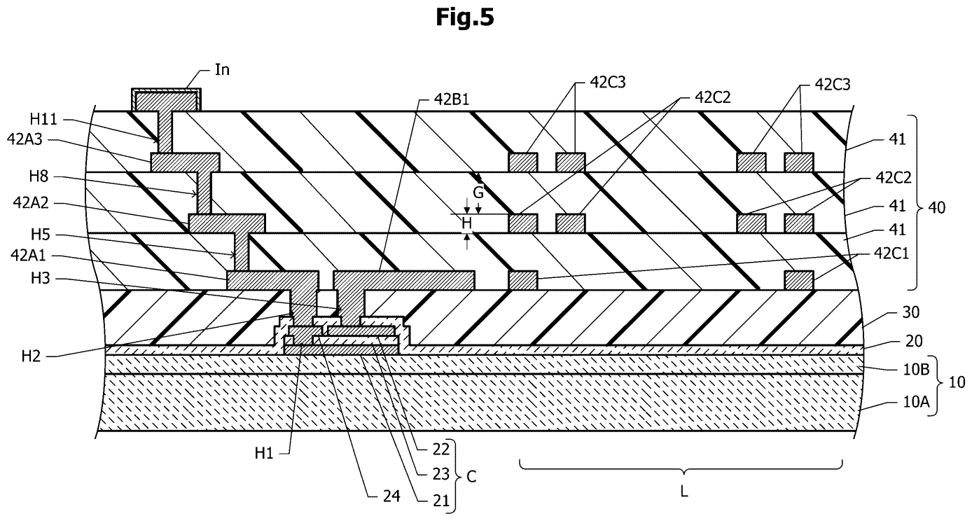

FIG. 5 is a cross-sectional view taken along single-dot dash line 5-5 in FIG. 2A.

The support substrate 10 is composed of a base substrate 10A and a base insulating film 10B covering the upper surface of the base substrate 10A. For example, single crystal silicon, a ceramic, aluminum nitride, glass, or the like may be used as the base substrate 10A. Alternatively, a substrate obtained by oxidizing the surface of a single crystal silicon substrate may be used. The base insulating film 10B may be composed of, for example, an insulating material primarily containing Si and O as constituent elements, or an insulating material primarily containing Si and N as constituent elements.

The lower electrode 21 is disposed on a portion of the surface (hereinafter referred to as the upper surface) of the base insulating film 10B facing away from the base substrate 10A. The dielectric film 23 is disposed on the upper surface of the lower electrode 21, and the upper electrode 22 and the conductor pattern 24 are disposed on top of the dielectric film 23. The conductor pattern 24 is connected to the lower electrode 21 through the via hole H1 provided in the dielectric film 23. The materials used for the lower electrode 21, upper electrode 22, and the conductor pattern 24 are the same as those used for the lower electrode 21 and the upper electrode 22 of the integrated passive component according to the First Embodiment (FIG. 1). The material used for the dielectric film 23 is the same as that used for the dielectric film 23 of the capacitor C of the integrated passive component according to the First Embodiment (FIG. 1).

The first insulating film 20 composed of an inorganic insulating material is disposed on the upper surface of the support substrate 10 so as to cover the capacitor C consisting of the lower electrode 21, the upper electrode 22, and the dielectric film 23, and the conductor pattern 24.

The second insulating film 30 composed of an insulating resin is disposed on the first insulating film 20. The multilayer wiring layer 40 is disposed on the second insulating film 30. The multilayer wiring layer 40 includes the first wiring layer, the second wiring layer, and the third wiring layer stacked in this order from the second insulating film 30, the third insulating films 41 that insulate these wiring layers from each other, and the third insulating film 41 that covers the third wiring layer. The materials used for the second insulating film 30 and the third insulating films 41 are the same as the materials used for the second insulating film 30 and the third insulating films 41 of the integrated passive component according to the First Embodiment (FIG. 1).

The conductor patterns 42A1, 42B1, and 42C1 are disposed in the first wiring layer. The conductor pattern 42A1 is connected to the conductor pattern 24 through the via hole H2 formed in the second insulating film 30 and the first insulating film 20. The conductor pattern 42B1 is connected to the upper electrode 22 through the via hole H3 formed in the second insulating film 30 and the first insulating film 20. As illustrated in FIG. 3B, the conductor pattern 42C1 is continuous with the conductor pattern 42A1 at locations other than the cross section illustrated in FIG. 5.

The conductor patterns 42A2 and 42C2 are disposed in the second wiring layer. The conductor pattern 42A2 is connected to the conductor pattern 42A1 through the via hole H5 provided in the third insulating film 41 of a first layer. The conductor patterns 42A3 and 42C3 are disposed in the third wiring layer. The conductor pattern 42A3 is connected to the conductor pattern 42A2 through the via hole H8 provided in the third insulating film 41 of a second layer.

The input terminal In is disposed on the third insulating film 41 of a third layer. The input terminal In is connected to the conductor pattern 42A3 through the via hole H11 provided in the third insulating film 41 of the third layer. The material used for the conductor patterns in the multilayer wiring layer 40 is the same as the material used for the conductor patterns 42 of the integrated passive component according to the First Embodiment (FIG. 1).

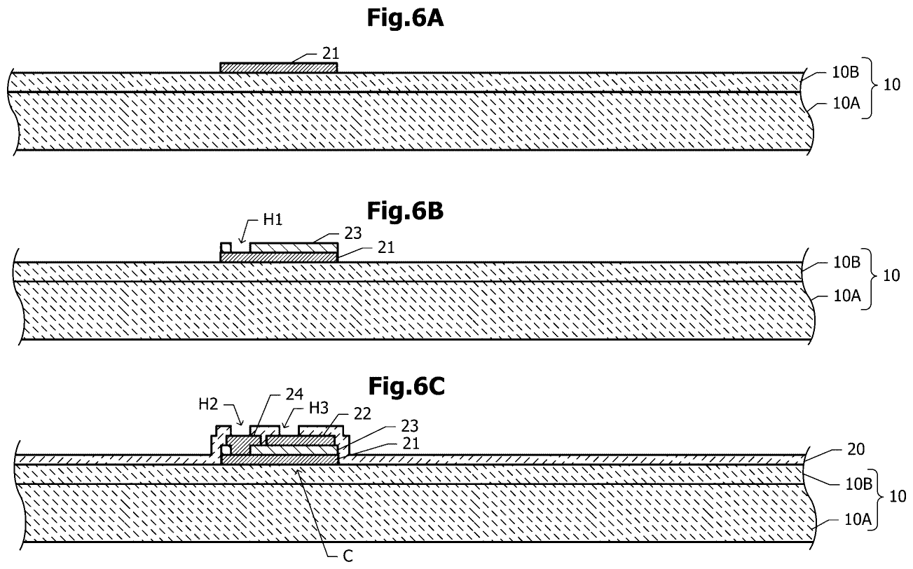

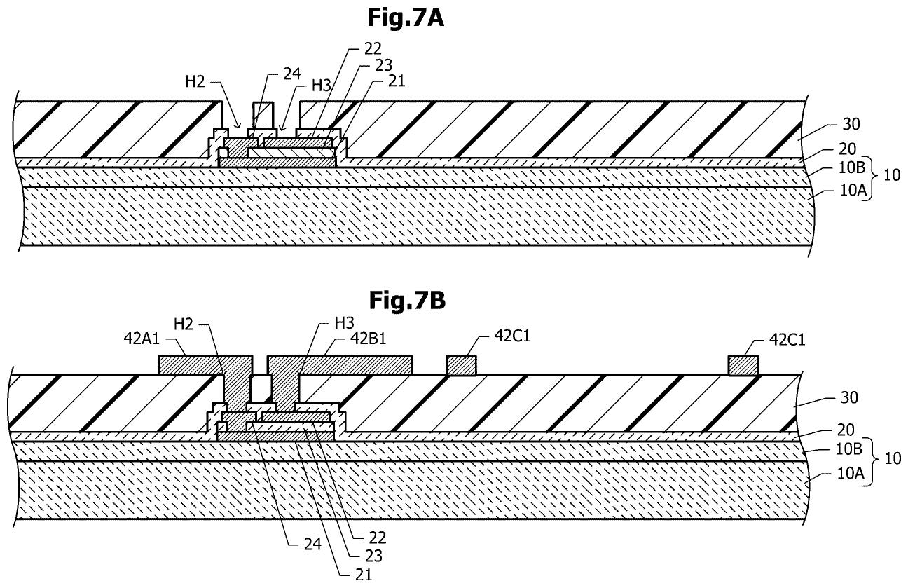

Next, a method for manufacturing the integrated passive component according to the Second Embodiment will be described with reference to FIGS. 6A to 7B. The cross-sectional views in FIGS. 6A to 7B are cross-sectional views of the integrated passive component according to the Second Embodiment at intermediate stages during its manufacture.

As illustrated in FIG. 6A, the base insulating film 10B composed of an inorganic insulating material such as amorphous SiN is formed on the upper surface of the base substrate 10A composed of an inorganic insulating material such as SiN ceramic. The base insulating film 10B can be formed using, for example, sputtering, plasma-enhanced chemical vapor deposition (plasma CVD), or metal-organic chemical vapor deposition (MOCVD). Through these steps, the support substrate 10 is formed, consisting of the base substrate 10A and the base insulating film 10B. The lower electrode 21 is formed on the upper surface of the support substrate 10. The lower electrode 21 can be formed using, for example, vacuum deposition or a lift-off method.

As illustrated in FIG. 6B, the dielectric film 23 having the via hole H1 provided therein is formed on the lower electrode 21. The dielectric film 23 may be composed of, for example, amorphous SiN. The dielectric film 23 may be formed using, for example, sputtering, plasma CVD, or MOCVD. The dielectric film 23 may be patterned and the via hole H1 may be formed by, for example, performing dry etching. In FIG. 6B, the dielectric film 23 is left only on the lower electrode 21 and not on the upper surface of the support substrate 10. However, the dielectric film 23 may also be left on the upper surface of the support substrate 10.

As illustrated in FIG. 6C, the upper electrode 22 and the conductor pattern 24 are formed on the dielectric film 23. The methods for forming and patterning the upper electrode 22 and the conductor pattern 24 are the same as those for forming and patterning the lower electrode 21. Through the steps up to this point, the capacitor C including the lower electrode 21, the upper electrode 22, and the dielectric film 23 is formed.

The first insulating film 20 is formed so as to cover the upper surface of the support substrate 10 and the capacitor C, and then the via holes H2 and H3 are formed. The first insulating film 20 can be formed using, for example, sputtering, plasma CVD, MOCVD, etc. The via holes H2 and H3 can be formed using, for example, dry etching.

As illustrated in FIG. 7A, the second insulating film 30 is formed on the first insulating film 20. Vacuum lamination, spin coating, or the like can be used to form the second insulating film 30. After that, the via holes H2 and H3 are formed through the second insulating film 30 at positions that overlap the via holes H2 and H3 provided in the first insulating film 20 in plan view. When a resin containing a photosensitive material is used as the second insulating film 30, the via holes H2 and H3 can be formed by performing exposure and development. When a resin not containing a photosensitive material is used as the second insulating film 30, the via holes H2 and H3 can be formed through irradiation with an ultraviolet laser.

As illustrated in FIG. 7B, the conductor patterns 42A1, 42B1, and 42C1 are formed on the second insulating film 30. The conductor patterns 42A1, 42B1, and 42C1 can be formed using, for example, a semi-additive method. The conductor pattern 42A1 is connected to the conductor pattern 24 through the via hole H2, and the conductor pattern 42B1 is connected to the upper electrode 22 through the via hole H3. Thereafter, as illustrated in FIG. 5, the third insulating films 41 and conductor patterns of the multilayer wiring layer 40 are stacked in an alternating manner on the second insulating film 30.

Next, an example of the dimensions of each component of the integrated passive component according to the Second Embodiment will be described.

The thickness of the support substrate 10 is 100 μm or less. The thickness of the capacitor C is about 1 μm. The thickness of the first insulating film 20 is 1 μm or more. The thickness of the second insulating film 30 is 1 μm or more. The thickness of each of the multiple third insulating films 41 is 10 μm or more. The thickness H of the multiple conductor patterns in the multilayer wiring layer 40 is 5 μm or more. The height of the input terminal In for external connection, etc. is about 70 μm.

The thickness H (FIG. 5) of each of the conductor patterns 42C1, 42C2, and 42C3 constituting the inductor L is greater than the thickness of each of the lower electrode 21 and upper electrode 22 of the capacitor C. Furthermore, a spacing G (FIG. 5), in the thickness direction, of the conductor patterns in the multilayer wiring layer 40 is equal to or greater than the thickness H of the conductor patterns.

Next, the excellent effects of the Second Embodiment will be described.

In the Second Embodiment, as in the First Embodiment, a high-toughness resin material is used for the second insulating film 30, and therefore the occurrence of cracks and peeling can be suppressed. Furthermore, the conductor patterns 42C1, 42C2, and 42C3 constituting the inductor L are disposed across multiple wiring layers of the multilayer wiring layer 40, thereby increasing the inductance value that can be designed. This makes it possible to obtain a high-performance compact integrated passive component.

In the Second Embodiment, the thickness of each of the conductor patterns 42C1, 42C2, and 42C3 constituting the inductor L is greater than the thickness of each of the lower electrode 21 and upper electrode 22 of the capacitor C. By making each of the conductor patterns 42C1, 42C2, and 42C3 constituting the inductor L relatively thick, the parasitic resistance of the inductor L can be reduced. Furthermore, by making the thickness of the lower electrode 21 and the upper electrode 22 of the capacitor C relatively small, the dimensional accuracy of the lower electrode 21 and the upper electrode 22 can be improved. This can increase the accuracy of the capacitance value of the capacitor C.

Furthermore, in the Second Embodiment, the spacing G between the conductor patterns in the multilayer wiring layer 40 in the thickness direction is greater than or equal to the thickness H of the conductor patterns. This reduces the parasitic capacitances between the conductor patterns that overlap in the thickness direction. Thus, the performance of the integrated passive component can be improved.

Furthermore, by using Cu or a metal material containing Cu as a main component for the conductor patterns in the multilayer wiring layer 40, it is easy to increase the thickness of the film, and it is possible to reduce the parasitic resistance of the conductor patterns.

### Third Practical Example

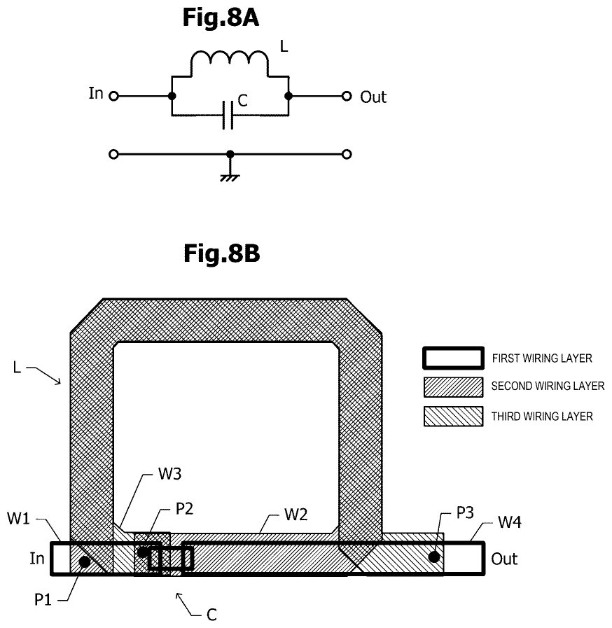

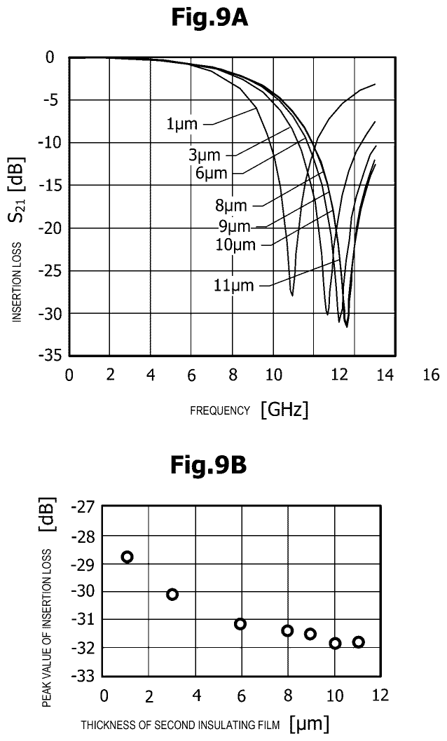

Next, an integrated passive component according to a Third Embodiment will be described with reference to FIGS. 8A, 8B, 9A, and 9B. Below, description of configurations common to the integrated passive component according to the Second Embodiment described with reference to FIGS. 2A to 7B is omitted.

FIG. 8A is an equivalent circuit diagram of the integrated passive component according to the Third Embodiment. In the Second Embodiment (FIG. 2B), the inductor L and the capacitor C form a low-pass filter, whereas in the Third Embodiment, an LC parallel resonant circuit is formed. The LC parallel resonant circuit is inserted between an input terminal In and an output terminal Out.

FIG. 8B is a diagram illustrating the positional relationship in plan view of the conductor patterns constituting the integrated passive component according to the Third Embodiment. The conductor patterns in the first wiring layer are represented by thick solid lines, the conductor patterns in the second wiring layer are represented by relatively dark hatching sloping upward to the right, and the conductor patterns in the third wiring layer are represented by relatively light hatching sloping downward to the right. One end portion of a conductor pattern W1 in the first wiring layer is connected to the input terminal In, and the other end portion is connected to one electrode of the capacitor C. One end portion of a conductor pattern W4 in the first wiring layer is connected to the other electrode of the capacitor C, and the other end portion is connected to the output terminal Out.

A conductor pattern W2 in the second wiring layer and a conductor pattern W3 in the third wiring layer form the inductor L. The conductor pattern W2 is disposed along the outer periphery of a square, and the conductor pattern W3 is disposed along three sides of the square along which the conductor pattern W2 extends. One end portion of the conductor pattern W2 is connected to the conductor pattern W1 at a connection point P1. The other end portion of the conductor pattern W2 is connected to one end portion of the conductor pattern W3 at a connection point P2. The other end portion of the conductor pattern W3 is connected to the conductor pattern W4 at a connection point P3.

In plan view, the capacitor C is disposed at a position overlapping the conductor pattern W2. The conductor patterns W1 and W4 are disposed to overlap one side of the square shape along which the conductor pattern W2 extends.

FIG. 9A is a graph illustrating simulation results of the insertion loss (S₂₁) of the integrated passive component according to the Third Embodiment. The horizontal axis represents frequency in units of GHz, and the vertical axis represents insertion loss in units of dB. Note that insertion loss is expressed as a negative value, and the larger the absolute value of S₂₁, the greater the insertion loss. The numerical values appended to the solid lines in FIG. 9A represent the thickness of the second insulating film 30 (FIG. 5). The simulation conditions other than the thickness of the second insulating film 30 are the same.

FIG. 9B is a graph illustrating the relationship between the peak value of insertion loss S₂₁ and the thickness of second insulating film 30. The horizontal axis represents the thickness of second insulating film 30 in units of μm, and the vertical axis represents the peak value of insertion loss S₂₁ in units of dB.

As illustrated in FIG. 9A, the resonant frequency increases as the thickness of the second insulating film 30 increases. As illustrated in FIGS. 9A and 9B, the peak value of the insertion loss S₂₁ increases in the negative direction as the thickness of the second insulating film 30 increases. It is also clear that the increase in the peak value of the insertion loss S₂₁ substantially saturates when the thickness of the second insulating film 30 is 10 μm or more.

The peak value of the insertion loss S₂₁ can be used to determine the approximate Q value (loss index) of the LC parallel resonant circuit. The more negative the peak value of the insertion loss S₂₁, the higher the Q value. By making the thickness of the second insulating film 30 10 μm or more, the electrical characteristics of the integrated passive component can be substantially optimized. This is because, when the second insulating film 30 is thicker, the distance in the thickness direction between the capacitor C and a conductor pattern in the multilayer wiring layer 40 increases, reducing the parasitic capacitance.

Next, the excellent effects of the Third Embodiment will be described.

In the Third Embodiment, it is possible to reduce the size of the integrated passive component by disposing the capacitor C and the inductor L so as to overlap in plan view. Furthermore, even when the capacitor C and the inductor L are disposed so as to overlap in plan view, deterioration of the electrical characteristics of the integrated passive component is suppressed by setting the thickness of the second insulating film 30 to 10 μm or more.

If the thickness of the second insulating film 30 is made too large, the parasitic inductance of the conductor patterns inside the via holes H2 and H3 (FIG. 5) provided in the second insulating film 30 increases. To suppress the increase in parasitic inductance, it is preferable to set the thickness of the second insulating film 30 to 20μm or less.

Each embodiment is merely an example and it goes without saying that parts of the configurations illustrated in different embodiments can be substituted for one another or combined with each other. Similar effects resulting from similar configurations of multiple embodiments are not be mentioned repeatedly for each embodiment. Furthermore, the present disclosure is not limited to the above-described embodiments. For example, it will be clear to a person skilled in the art that various changes, improvements and combinations are possible.

The following is disclosed based on the above embodiments described in the present specification.
<1>An integrated passive component comprising a support substrate; a capacitor disposed on an upper surface, which is one surface of the support substrate; a first insulating film disposed on the support substrate and covering the capacitor; a second insulating film disposed on the first insulating film; and a multilayer wiring layer including multiple wiring layers and multiple third insulating films stacked in an alternating manner on the second insulating film. The multilayer wiring layer includes an inductor constituted by conductor patterns in wiring layers, and a weight-average molecular weight of resin forming the second insulating film is greater than a weight-average molecular weight of resin forming the third insulating films.
<2>The integrated passive component according to <1>, wherein the second insulating film has a thickness of 10 μm or more.
<3>The integrated passive component according to <1>or <2>, wherein the conductor patterns constituting the inductor are disposed across multiple wiring layers within the multilayer wiring layer.
<4>The integrated passive component according to <3>, wherein a spacing, in a thickness direction, between the conductor patterns constituting the inductor is greater than or equal to a thickness of the conductor patterns.
<5>The integrated passive component according to any one of <1>to <4>, wherein the capacitor includes a dielectric film, and an upper electrode and a lower electrode disposed above and below the dielectric film, and the conductor patterns constituting the inductor are thicker than both the upper electrode and the lower electrode.
<6>The integrated passive component according to any one of <1>to <5>, wherein the conductor patterns constituting the inductor are composed of Cu or a metal material containing Cu as a main component.
<7>An integrated passive component comprising a support substrate; a capacitor disposed on an upper surface, which is one surface of the support substrate; a first insulating film disposed on the support substrate and covering the capacitor; a second insulating film disposed on the first insulating film; and a multilayer wiring layer including multiple wiring layers and multiple third insulating films stacked in an alternating manner on the second insulating film. The multilayer wiring layer includes an inductor constituted by conductor patterns in wiring layers, and breaking elongation of the resin forming the second insulating film is greater than breaking elongation of the resin forming the third insulating films.

What is claimed is:

1. An integrated passive component comprising:
a support substrate;
a capacitor on an upper surface, which is one surface of the support substrate;
a first insulating film on the support substrate and covering the capacitor;
a second insulating film on the first insulating film; and
a multilayer wiring layer including multiple wiring layers and multiple third insulating films stacked in an alternating manner on the second insulating film,
wherein
the multilayer wiring layer includes an inductor configured by conductor patterns in wiring layers, and
a weight-average molecular weight of resin in the second insulating film is greater than a weight-average molecular weight of resin in the third insulating films.

2. The integrated passive component according to claim 1, wherein
the second insulating film has a thickness of 10 μm or more.

3. The integrated passive component according to claim 1, wherein
the conductor patterns configuring the inductor are across multiple wiring layers in the multilayer wiring layer.

4. The integrated passive component according to claim 3, wherein
a spacing, in a thickness direction, between the conductor patterns configuring the inductor is equal to or greater than a thickness of the conductor patterns.

5. The integrated passive component according to claim 1, wherein
the capacitor includes a dielectric film, and an upper electrode and a lower electrode disposed above and below the dielectric film, and
the conductor patterns configuring the inductor are thicker than both the upper electrode and the lower electrode.

6. The integrated passive component according to claim 1, wherein
the conductor patterns configuring the inductor include Cu or a metal material containing Cu as a main component.

7. The integrated passive component according to claim 2, wherein
the conductor patterns configuring the inductor are across multiple wiring layers in the multilayer wiring layer.

8. The integrated passive component according to claim 7, wherein
a spacing, in a thickness direction, between the conductor patterns configuring the inductor is equal to or greater than a thickness of the conductor patterns.

9. The integrated passive component according to claim 2, wherein
the capacitor includes a dielectric film, and an upper electrode and a lower electrode disposed above and below the dielectric film, and
the conductor patterns configuring the inductor are thicker than both the upper electrode and the lower electrode.

10. The integrated passive component according to claim 3, wherein
the capacitor includes a dielectric film, and an upper electrode and a lower electrode disposed above and below the dielectric film, and
the conductor patterns configuring the inductor are thicker than both the upper electrode and the lower electrode.

11. The integrated passive component according to claim 4, wherein
the capacitor includes a dielectric film, and an upper electrode and a lower electrode disposed above and below the dielectric film, and
the conductor patterns configuring the inductor are thicker than both the upper electrode and the lower electrode.

12. The integrated passive component according to claim 7, wherein
the capacitor includes a dielectric film, and an upper electrode and a lower electrode disposed above and below the dielectric film, and
the conductor patterns configuring the inductor are thicker than both the upper electrode and the lower electrode.

13. The integrated passive component according to claim 8, wherein
the capacitor includes a dielectric film, and an upper electrode and a lower electrode disposed above and below the dielectric film, and
the conductor patterns configuring the inductor are thicker than both the upper electrode and the lower electrode.

14. The integrated passive component according to claim 2, wherein
the conductor patterns configuring the inductor include Cu or a metal material containing Cu as a main component.

15. The integrated passive component according to claim 3, wherein
the conductor patterns configuring the inductor include Cu or a metal material containing Cu as a main component.

16. The integrated passive component according to claim 4, wherein
the conductor patterns configuring the inductor include Cu or a metal material containing Cu as a main component.

17. The integrated passive component according to claim 5, wherein
the conductor patterns configuring the inductor include Cu or a metal material containing Cu as a main component.

18. The integrated passive component according to claim 7, wherein
the conductor patterns configuring the inductor include Cu or a metal material containing Cu as a main component.

19. The integrated passive component according to claim 8, wherein
the conductor patterns configuring the inductor include Cu or a metal material containing Cu as a main component.

20. An integrated passive component comprising:
a support substrate;
a capacitor on an upper surface, which is one surface of the support substrate;
a first insulating film on the support substrate and covering the capacitor;
a second insulating film on the first insulating film; and
a multilayer wiring layer including multiple wiring layers and multiple third insulating films stacked in an alternating manner on the second insulating film,
wherein
the multilayer wiring layer includes an inductor configured by conductor patterns in wiring layers, and
breaking elongation of resin in the second insulating film is greater than breaking elongation of resin in the third insulating films.
